(19) United States
(12) Patent Application Publication
(10) Pub. No.: US 2020/0395492 A1
(43) Pub. Date: Dec. 17, 2020

(54) DYE SENSITIZED PHOTOVOLTAIC CELLS

(71) Applicant: AMBIENT PHOTONICS, INC., Mill Valley, CA (US)

(72) Inventors: Kethinni G. Chittibabu, Mill Valley, CA (US); John C. Warner, Mill Valley, CA (US)

(73) Assignee: AMBIENT PHOTONICS, INC., Mill Valley, CA (US)

(21) Appl. No.: 17/003,298

(22) Filed: Aug. 26, 2020

Related U.S. Application Data
(63) Continuation of application No. PCT/US2019/051849, filed on Sep. 19, 2019.
(60) Provisional application No. 62/734,511, filed on Sep. 21, 2018.

(51) Int. Cl. H01L 31/0216; H01L 31/18; H01G 9/20

(52) U.S. Cl. CPC H01L 31/02164; H01L 31/1884; H01G 9/2059; H01G 9/2031; H01L 31/186

(57) ABSTRACT

Provided herein are improvements to dye-sensitized photovoltaic cells that enhance the ability of those cells to operate in normal room lighting conditions. These improvements include printable, non-corrosive, nonporous hole blocking layer formulations that improve the performance of dye-sensitized photovoltaic cells under 1 sun and indoor light irradiation conditions. Also provided herein are highly stable electrolyte formulations for use in dye-sensitized photovoltaic cells. These electrolytes use high boiling solvents, and provide unexpectedly superior results compared to prior art acetonitrile-based electrolytes. Also provided herein are chemically polymerizable formulations for depositing thin composite catalytic layers for redox electrolyte-based dye-sensitized photovoltaic cells. The formulations allow R2R printing (involves coating, fast chemical polymerization, rinsing of catalytic materials with methanol) composite catalyst layers on the cathode. In situ chemical polymerization process forms very uniform thin films, which is essential for achieving uniform performance from every cell in serially connected photovoltaic module.

### BACKGROUND

Sensitization of semiconductor solids such as metal oxides in imaging devices, memories, sensors, and photovoltaic cells can serve as an effective means of energy transduction. These devices use metal oxides, such as titanium dioxide that are transparent to light but can be sensitized to the desired spectrum through the use of sensitizing agents that absorb light energy and transduce it into electrical power or an electrical signal. This sensitization occurs through charge injection into the metal oxide from the excited state of the dye sensitizer. Sensitizers such as transition metal complexes, inorganic colloids and organic dye molecules are used.

Prominent among such technologies is the dye-sensitized metal oxide photovoltaic cell (DSPC). DSPCs use a dye to absorb light and initiate a rapid electron transfer to a nanostructured oxide such as TiO₂. The mesoscopic structure of the TiO₂ allows building of thick, nanoporous films with active-layer thicknesses of several microns. The dye is then adsorbed on the large surface area of the mesoporous TiO₂. Charge balance and transport is achieved by a layer having a REDOX couple, such as iodide/triiodide, Co(II)/Co(III) complexes, and Cu(I)/Cu(II) complexes.

Dyes based on transition metal complexes are disclosed in Gratzel et al., U.S. Pat. Nos. 4,927,721 and 5,350,644. These dye materials are disposed on mesoporous metal oxides that have a high surface area on which the absorbing, sensitizing layer can be formed. This results in a high absorptivity of light in the cell. Dyes such as Ru(II) (2,2′-bipyridyl 4,4′ dicarboxylate)₂ (NCS)₂ have been found to be efficient sensitizers and can be attached to the metal oxide solid through carboxyl or phosphonate groups on the periphery of the compounds. However, when transition metal ruthenium complexes are used as sensitizers they must be applied to the mesoporous metal oxide layers in a coat as thick as 10 micrometers or thicker to absorb enough radiation to attain sufficient power conversion efficiencies. Further, the ruthenium complexes are expensive. In addition, such dyes must be applied using volatile organic solvents, co-solvents, and diluents because they are not dispersible in water. Volatile organic compounds (VOCs) are significant pollutants that can affect the environment and human health. While VOCs are usually not acutely toxic, they may have chronic health and environmental effects. For this reason, governments around the world are seeking to reduce the levels of VOCs.

One type of dye-sensitized photovoltaic cell is known as the Gratzel cell. Hamann et al. (2008), “Advancing beyond current generation dye-sensitized solar cells,” Energy Environ. Sci. 1:66-78 (the disclosure of which is incorporated in its entirety by reference), describes the Gratzel cell. The Gratzel cell includes crystalline titanium dioxide nanoparticles serving as a photoanode in the photovoltaic cell. The titanium dioxide is coated with light sensitive dyes. The titanium dioxide photoanode includes 10-20 nm diameter titanium dioxide particles forming a 12 μm transparent film. The 12 μm titanium dioxide film is made by sintering the 10-20 nm diameter titanium dioxide particles so that they have a high surface area. The titanium dioxide photoanode also includes a 4 μm film of titanium dioxide particles having a diameter of about 400 nm. The coated titanium dioxide films are located between two transparent conducting oxide (TCO) electrodes. Also disposed between the two TCO electrodes is an electrolyte with a redox shuttle.

The Gratzel cell may be made by first constructing a top portion. The top portion may be constructed by depositing fluorine-doped tin dioxide (SnO₂F) on a transparent plate, which is usually glass. A thin layer of titanium dioxide (TiO₂) is deposited on the transparent plate having a conductive coating. The TiO₂ coated plate is then dipped into a photosensitized dye such as ruthenium-polypyridine dye in solution. A thin layer of the dye covalently bonds to the surface of the titanium dioxide. A bottom portion of the Gratzel cell is made from a conductive plate coated with platinum metal. The top portion and the bottom portion are then joined and sealed. The electrolyte, such as iodide-triiodide, is then typically inserted between the top and bottom portions of the Gratzel cell.

Typically, thin films for DSPCs are composed of a single metal oxide—usually titanium dioxide, which in addition to nanoparticles, may be utilized in the form of larger 200 to 400 nm scale particles or as dispersed nanoparticles formed in situ from a titanium alkoxide solution. In one embodiment, the present application discloses the use of multiple morphologies of titanium oxide as well as other metal oxides, which provide a boost in efficiency over the single metal oxide system. The additional metal oxides that may be employed include, but are not limited to, alpha aluminum oxide, gamma aluminum oxide, fumed silica, silica, diatomaceous earth, aluminum titanate, hydroxyapatite, calcium phosphate and iron titanate; and mixtures thereof. These materials may be utilized in conjunction with traditional titanium oxide thin films or with a thin film dye-sensitized photovoltaic cell system

In operation, the dye absorbs sunlight, which results in the dye molecules becoming excited and transmitting electrons into the titanium dioxide. The titanium dioxide accepts the energized electrons, which travel to a first TCO electrode. Concurrently, the second TCO electrode serves as a counter electrode, which uses a redox couple such as iodide-triiodide (I³⁻/I⁻) to regenerate the dye. If the dye molecule is not reduced back to its original state, the oxidized dye molecule decomposes. As the dye-sensitized photovoltaic cell undergoes many oxidation-reduction cycles in the lifetime of operation, more and more dye molecules undergo decomposition over time, and the cell energy conversion efficiency decreases.

Hattori and coworkers (Hattori, S., et al. (2005) “Blue copper model complexes with distorted tetragonal geometry acting as effective electron-transfer mediators in dye-sensitized photovoltaic cells. J. Am. Chem. Soc., 127: 9648-9654) have used copper (I/II) redox couples in DSPCs using ruthenium-based dyes, with very low resulting efficiencies. Peng Wang and his coworkers improved the performance of copper redox-based dye DSPCs using an organic dye (Bai, Y., et al. (2011) Chem. Commun., 47: 4376-4378). The voltage generated from such cells far exceeded voltage generated by any iodide/triiodide based redox couple.

Generally, platinum, graphenes or poly (3,4-ethyelenedioxythiophene) (“PEDOT”) are used in dye-sensitized photovoltaic cells. Platinum is either deposited by pyrolytic decomposition of hexachloroplatinic acid at temperatures exceeding 400° C., or by sputtering. PEDOT is generally deposited by electrochemical polymerization of 3,4-ethylenedioxythiophene (“EDOT”), which create uniformity issues due to high resistance substrates used as cathode materials. Graphene materials are generally deposited by spin coating from graphene material containing solution or suspension. Although graphene materials work better than PEDOT and platinum, it is difficult to bond graphenes to the substrate, often causing delamination problems. Moreover, the deposition from spin coating often results in non-uniform films due to absence of cohesive forces between graphene molecules. Electrochemical deposition of PEDOT can be adequate for smaller devices but is unsuited for larger devices. Uniformity issues arise when the substrate size increases due to current drop across the length due to ohmic losses (polymerization kinetics depends on the current flow in a given time). This is not an ideal process for R2R manufacturing. Chemically polymerized PEDOT/PSS solution available from commercial sources is often used in electronic device applications. This material is highly water-soluble; as a result, devices produced using this solution suffer from decreased useful life due to dissociation from the cathode, and also due to acidity that degrades the transparent conducting electrodes on the device.

### SUMMARY

Provided herein are printable, non-corrosive, nonporous hole blocking layer formulations that improve the performance of dye-sensitized photovoltaic cells under 1 sun and indoor light irradiation conditions. The nonporous hole blocking layer is introduced between electrode (anode) and nanoporous TiO₂ film. The nonporous hole blocking layer reduces/inhibits back electron transfer between redox species in the electrolyte and the electrode. Also provided is a process for introducing a nonporous hole blocking layer which employs benign materials (titanium alkoxides, polymeric titanium alkoxides, other organotitanium compounds) and can be coated in high speed rolls.

Also provided herein are highly stable electrolyte formulations for use in dye-sensitized photovoltaic cells. These electrolytes employ high boiling solvents, and provide unexpectedly superior results compared to prior art acetonitrile-based electrolytes, which use low boiling nitrile solvents, such as acetonitrile. These electrolyte formulations are critical for fabricating stable indoor light harvesting photovoltaic cells. The performance of these photovoltaic cells exceeds the performance of the previous best photovoltaic cells (gallium arsenide-based) under indoor light exposure (50 to 5000 lux).

Also provided herein are chemically polymerizable formulations for depositing thin composite catalytic layers for redox electrolyte-based dye-sensitized photovoltaic cells. The formulations allow R2R printing (involves coating, fast chemical polymerization, rinsing of catalytic materials with methanol) composite catalyst layers on the cathode. In situ chemical polymerization process forms very uniform thin films, which is essential for achieving uniform performance from every cell in serially connected photovoltaic module.

### BRIEF DESCRIPTION OF THE DRAWINGS

FIG. 1 is a schematic diagram illustrating the general architecture of a dye-sensitized photovoltaic cell as described herein.

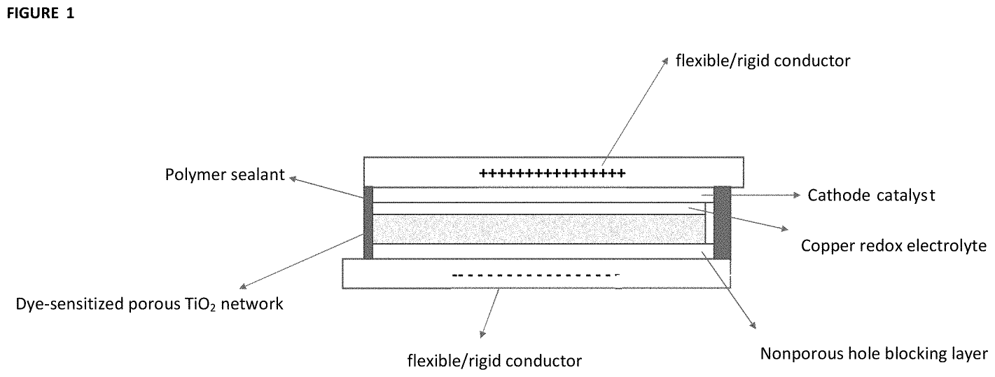

### DETAILED DESCRIPTION

### Definitions

Unless specifically noted otherwise herein, the definitions of the terms used are standard definitions used in the art of organic chemistry. Exemplary embodiments, aspects and variations are illustrated in the figures and drawings, and it is intended that the embodiments, aspects and variations, and the figures and drawings disclosed herein are to be considered illustrative and not limiting.

While particular embodiments are shown and described herein, it will be obvious to those skilled in the art that such embodiments are provided by way of example only. Numerous variations, changes, and substitutions will now occur to those skilled in the art. It should be understood that various alternatives to the embodiments described herein may be employed in practicing the methods described herein. It is intended that the appended claims define the scope of the invention and that methods and structures within the scope of these claims and their equivalents be covered thereby.

Unless defined otherwise, all technical and scientific terms used herein have the same meaning as is commonly understood by one of skill in the art. All patents and publications referred to herein are incorporated by reference.

As used in the specification and claims, the singular form “a,” “an,” and “the” include plural references unless the context clearly dictates otherwise.

Abbreviations and acronyms used herein:

### ACN—Acetonitrile.

### DSPC—Dye-Sensitized Photovoltaic Cell.

DI—deionized.
EDOT—3,4-ethylenedioxythiophene.

### FF—Fill Factor.

### FTO—Fluoride-doped Tin Oxide.

### GBL—Gamma-butyrolactone.

J_{sc}—Short-circuit current density.
MPN—3-methoxypropionitrile
PEDOT—Poly(3,4-ethyelenedioxythiophene)
PEN—polyethylene napthalate
PET—polyethylene terephthalate
PSS—poly(4-styrene sulfonic acid)
SDS—sodium dodecyl sulfate.
TBHFP—Tetra-n-butylammonium hexafluorophosphate.
V_{oc}—Open circuit voltage.

### VOC—Volatile Organic Compound.

“Graphene” is an allotrope of carbon consisting of a single layer of carbon atoms arranged in a hexagonal lattice.

A “hole-blocking” layer in a photovoltaic cell is a nonporous layer disposed between the cathode and anode which reduces and/or inhibits back-transfer of electrons from the electrolyte to the anode.

The dye-sensitized photovoltaic cells described herein comprise:

a cathode;
an electrolyte;
a porous dye-sensitized titanium dioxide film; and
an anode.

Also provided herein are dye-sensitized photovoltaic cells which comprise a nonporous hole-blocking layer interposed between the anode and the dye-sensitized titanium dioxide film. The nonporous “hole-blocking” layer may comprise an organotitanium compound, such as a titanium alkoxide. The organotitanium compound may be polymeric, such as a polymeric titanium alkoxide. An exemplary polymeric titanium alkoxide is poly(n-butyl titanate). The nonporous or compact hole-blocking layer may also comprise titanium in the form of an oxide, such as compact anatase or rutile film. The thickness of the hole blocking layer may be from about 20 nm to about 100 nm.

The anode may comprise a transparent conducting oxide (TCO)-coated glass, a TCO coated transparent plastic substrate, or a thin metal foil. Exemplary transparent conducting oxides include fluorine-doped tin oxide, indium-doped tin oxide, and aluminum-doped tin oxide. Exemplary transparent plastic substrates may comprise PET or PEN.

Also provided herein is a method of preparing a dye-sensitized photovoltaic cell as described above, comprising the step of applying the nonporous blocking layer on the anode. The nonporous blocking layer may be applied to the anode using art-known techniques, such as gravure, silkscreen, slot, spin or blade coating.

The dye-sensitized photovoltaic cell described herein comprises an electrolyte. In some embodiments the electrolyte may comprise a redox couple. In some embodiments the redox c couple comprises organocopper (I) and organocopper (II) salts. Suitable organocopper salts include copper complexes comprising bi- and polydentate organic ligands with counterions. Suitable bidentate organic ligands include, but are not limited to, 6,6′-dialkyl-2,2′-bipyridine; 4,4′,6,6′-tetralkyl-2,2′-bipyridine; 2,9-dialkyl-1,10-phenathroline; 1,10-phenathroine; and 2,2′-bipyridine. Suitable counterions include, but are not limited to, bis(trifluorosulfon)imide, hexafluorophosphate, and tetrafluoroborate. The ratio of organocopper(I) to organocopper(II) salts may be from about 4:1 to about 12:1. Alternatively, the ratio of organocopper(i) to organocopper(II) salts may be from about 6:1 to about 10:1.

The redox couple may comprise copper complexes with more than one ligand. For example, the redox couple may comprise a copper (I) complex with 6,6′-dialkyl-2,2′-bipyridine and a copper (II) complex with a bidentate organic ligand selected from the group consisting of 6,6′-dialkyl-2,2′-bipyridine; 4,4′,6,6′-tetralkyl-2,2′-bipyridine; 2,9-dialkyl-1,10-phenathroline; 1,10-phenathroine; and 2,2′-bipyridine. Alternatively, the redox couple may comprise a copper (I) complex with 2,9-dialkyl-1,10-phenathroline and a copper (II) complex with a bidentate organic ligand selected from the group consisting of 6,6′-dialkyl-2,2′-bipyridine; 4,4′,6,6′-tetralkyl-2,2′-bipyridine; 2,9-dialkyl-1,10-phenathroline; 1,10-phenathroine; and 2,2′-bipyridine.

The dye-sensitized photovoltaic cell described herein comprises an electrolyte, which may comprise two or more solvents. Suitable solvents include, but are not limited to, sulfolane, dialkylsulfone, an alkoxypropionitrile, cyclic carbonates, acyclic carbonates, cyclic lactones, acyclic lactones, low viscosity ionic liquids and binary/tertiary/quaternary mixtures of these solvents. In an exemplary embodiment, the electrolyte comprises at least 50% sulfolane or dialkyl sulfone. Alternatively, the electrolyte may comprise up to about 50% of 3-alkoxypropionitrile, cyclic and acyclic lactones, cyclic and acyclic carbonates, low viscosity ionic liquids, or binary/tertiary/quaternary mixtures thereof. The electrolyte may also comprise up to about 0.6M N-methylbenzimidazole and up to about 0.2 M lithium bis(trifluorosulfon)imide as additives.

In some embodiments, the dye-sensitized photovoltaic cell described herein further comprises a cathode catalyst disposed on the cathode. A suitable cathode catalyst may comprise a mixture of 2D conductor and electronic conducting polymer. A “2D conductor” is a molecular semiconductor with thickness in atomic scale. Exemplary 2D conductors include graphenes, transition metal dichalcogenides (ex., molybdenum disulfide or diselenide), or hexagonal boron nitride. For use in the cathode catalysts described herein, the graphene may comprise a molecular layer or nano/micro crystal. The graphene may be derived from reduced graphene oxide. Suitable conducting polymers include but are not limited to polythiophene, polypyrrole, polyaniline, and derivatives thereof. An exemplary polythiophene for use in the photovoltaic cell described herein is PEDOT.

In one alternative embodiment, the present application provides a dye-sensitized photovoltaic cell comprising a cathode; an electrolyte; a porous dye-sensitized titanium dioxide film layer; an anode; and a nonporous hole-blocking layer interposed between the anode and the dye-sensitized titanium dioxide film layer; wherein the electrolyte comprises a redox couple comprising organocopper (I) and organocopper (II) salts, and wherein the ratio of organocopper (I) to organocopper (II) salts is from about 4:1 to about 12:1.

In another alternative embodiment, the present application provides a dye-sensitized photovoltaic cell comprising a cathode; an electrolyte; a porous dye-sensitized titanium dioxide film layer; an anode; and a nonporous hole-blocking layer interposed between the anode and the dye-sensitized titanium dioxide film layer; wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; an anode; and a nonporous hole-blocking layer interposed between the anode and the dye-sensitized titanium dioxide film layer.

In another alternative embodiment, the present application provides a dye-sensitized photovoltaic cell comprising a cathode; an electrolyte; a porous dye-sensitized titanium dioxide film layer; and an anode; wherein the electrolyte comprises a redox couple comprising organocopper (I) and organocopper (II) salts, and wherein the ratio of organocopper (I) to organocopper (II) salts is from about 4:1 to about 12:1; and wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; and an anode; wherein the electrolyte comprises a redox couple comprising organocopper (I) and organocopper (II) salts, and wherein the ratio of organocopper (I) to organocopper (II) salts is from about 4:1 to about 12:1.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; and an anode; wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; an electrolyte; a porous dye-sensitized titanium dioxide film layer; an anode; and a nonporous hole-blocking layer interposed between the anode and the dye-sensitized titanium dioxide film layer; wherein the electrolyte comprises a redox couple comprising organocopper (I) and organocopper (II) salts, and wherein the ratio of organocopper (I) to organocopper (II) salts is from about 4:1 to about 12:1; and herein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; an anode; and a nonporous hole-blocking layer interposed between the anode and the dye-sensitized titanium dioxide film layer; wherein the electrolyte comprises a redox couple comprising organocopper (I) and organocopper (II) salts, and wherein the ratio of organocopper (I) to organocopper (II) salts is from about 4:1 to about 12:1.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; an anode; and a nonporous hole-blocking layer interposed between the anode and the dye-sensitized titanium dioxide film layer; wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; and an anode; wherein the electrolyte comprises a redox couple comprising organocopper (I) and organocopper (II) salts, and wherein the ratio of organocopper (I) to organocopper (II) salts is from about 4:1 to about 12:1; wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

In another alternative embodiment, the present application provides a dye-sensitized photovoltaic cell comprising a cathode; a cathode catalyst disposed on the cathode, wherein the cathode catalyst comprises a 2D conductor and an electronic conducting polymer; an electrolyte; a porous dye-sensitized titanium dioxide film layer; an anode; and a nonporous hole-blocking layer interposed between the anode and the dye-sensitized titanium dioxide film layer; wherein the electrolyte comprises a redox couple comprising organocopper (I) and organocopper (II) salts, and wherein the ratio of organocopper (I) to organocopper (II) salts is from about 4:1 to about 12:1; wherein the electrolyte comprises two or more solvents selected from the group consisting of sulfolane, dialkylsulfone, an alkoxypropionitrile, cyclic carbonates, acyclic carbonates, cyclic lactones, acyclic lactones, low viscosity ionic liquids, and binary/tertiary/quaternary mixtures of these solvents.

Also provided herein is a method of producing a photovoltaic cell of claim comprising the step of polymerizing PEDOT on the cathode from monomeric EDOT. The PEDOT may be polymerized on the cathode by chemical polymerization or electrochemical polymerization. The PEDOT is may be polymerized on the cathode using ferric tosylate or ferric chloride as a catalyst. The ratio of EDOT to ferric chloride may be from about 1:3 to about 1:4. In one embodiment, EDOT is mixed with graphene before chemical polymerization. The EDOT/graphene/ferric catalysis may be deposited from n-butanol on the cathode using spin, gravure, blade or slot coating techniques and allowed to polymerize on the substrate.

Also provided herein is a method for forming composite catalytic layers on the cathode of a dye-sensitized photovoltaic cell, comprising the step of forming a composite graphene material with one or more conducting polymers. Suitable conducting polymers include, but are not limited to, polythiophenes, polypyrroles, and polyanilines. The ratio of graphene to conducting polymer may be from about 0.5:10 to about 2:10. A suitable polythiophene for use in this method is PEDOT. In one alternative embodiment of the method, the polymer and graphenes are polymerized prior to deposition on the cathode. The composite may be formed by the steps of depositing graphene on an electrode to form a graphene layer; and electrodepositing the polymer on the graphene layer.

### EXAMPLES

### Example 1—Blocking Layer

Blocking layers were applied on a fluorine doped tin oxide (FTO) coated glass using 0.1 to 1% of Tyzor™ poly(n-butyl titanate) solution in n-butanol by spin or blade coating technique. An aqueous dispersion containing 20% by weight of TiO₂ (Degussa P25 with a particle size of 21±5 nm) and 5% by weight of poly(4-vinyl pyridine) was prepared and applied on the prepared electrodes with and without blocking layer using blade coating technique. The thickness of the TiO₂ layer was ca. 6 microns. The TiO₂ coating was sintered at 500° C. for 30 minutes, cooled to 80° C. and immersed in a 1:1 acetonitrile/t-butanol dye solution containing 0.3 mM D35 dye (Dyenamo, Stockholm, SE)(see structure at end of Examples) and 0.3 mM deoxycholic acid. The anodes were kept in dye solution overnight, rinsed with acetonitrile and air dried in the dark. The dye-sensitized anode was sandwiched with pyrolytically deposited platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in acetonitrile was injected between anode and cathode using pinhole on the cathode. The pinhole was sealed using Meltonix/glass cover using heat sealing process. A conductive silver paint was applied on the contact areas of anode and cathode and dried to form electrical contact.

The photovoltaic performance of the fabricated cell was measured under AM 1.5 conditions at a light intensity of 97 mW/cm². Two cells were fabricated for each set (denoted as cell 1 and cell 2). The photovoltaic performance of fabricated photovoltaic cells was characterized using open circuit voltage (V_{oc} in mV), short circuit current density (J_{sc} in milliamperes/square centimeter), fill factor and overall conversion efficiency (in %) and shown in Table 1. The fill factor (FF) is defined as the ratio of the maximum power from the photovoltaic cell to the product of V_{oc} and J_{sc}.

TABLE 1
Photovoltaic characteristics of P25 based photovoltaic cells made
with and without blocking layer under 1 sun irradiation conditions

| | Blocking | | | | |
|---|---|---|---|---|---|
| | layer | | Jsc | | Effi- |
| | deposited | Voc | (mA/ | Fill | ciency |
| Sample | from | (mV) | cm²) | factor | (%) |
| No blocking layer- | 0% Tyzor ™ | 1039.63 | 8.46 | 0.400 | 3.529 |
| cell 1 | in n-butanol | | | | |
| No blocking layer- | 0% Tyzor ™ | 1029.82 | 8.90 | 0.406 | 3.733 |
| cell 2 | in n-butanol | | | | |
| Blocking layer 1- | 0.15% | 1042.07 | 9.16 | 0.436 | 4.185 |
| cell 1 | Tyzor ™ | | | | |
| | in n-butanol | | | | |
| Blocking layer 1- | 0.15% | 1036.02 | 8.84 | 0.446 | 4.101 |
| cell 2 | Tyzor ™ in | | | | |
| | n-butanol | | | | |
| Blocking layer 2- | 0.3% Tyzor ™ | 1032.92 | 10.69 | 0.462 | 5.125 |
| cell 1 | in n-butanol | | | | |
| Blocking layer 2- | 0.3% Tyzor ™ | 1035.38 | 10.60 | 0.443 | 4.881 |
| cell 2 | in n-butanol | | | | |

### Example 2—Blocking Layer

Blocking layers were applied on a fluorine doped tin oxide (FTO) coated glass using 0.1 to 1% of Tyzor™ poly(n-butyl titanate) solution in n-butanol by spin or blade coating technique. Photoelectrodes were made with and without blocking layer on FTO coated glass using an aqueous colloidal TiO₂ (18 nm particle size). The thickness of the TiO₂ layer was ca. 6 microns. The TiO₂ coating was sintered at 500° C. for 30 minutes, cooled to 80° C. and immersed in a 1:1 acetonitrile/t-butanol dye solution containing 0.3 mM D35 dye (Dyenamo, Sweden) and 0.3 mM deoxycholic acid. The anodes were kept in dye solution overnight, rinsed with acetonitrile and air dried in the dark. The dye-sensitized anode was sandwiched with pyrolytically deposited platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (11) bis(trifluorosulfon)imide, 100 mM of lithium bis(trifluorosulfon)imide and 0.5 M 4-(tertiarybutyl)pyridine in acetonitrile was injected between anode and cathode using pinhole on the cathode. The pinhole was sealed using Meltonix/glass cover using heat sealing process. A conductive silver paint was applied on the contact areas of anode and cathode and dried to form electrical contact. Two cells were fabricated for each set (denoted as cell 1 and cell 2).

The photovoltaic performance of the fabricated cell was measured under AM 1.5 conditions at a light intensity of 97 mW/cm². The performance of fabricated photovoltaic cells was characterized using open circuit voltage (V_{oc} in mV), short circuit current density (J_{sc} in milliamperes/square centimeter), fill factor and overall photovoltaic conversion efficiency (in %) and shown in Table 2. The fill factor (FF) is defined as the ratio of the maximum power from the photovoltaic cell to the product of V_{oc} and J_{sc}.

TABLE 2
Photovoltaic characteristics of 18 nm TiO2 based
photovoltaic cells made with and without blocking
layer under 1 sun irradiation conditions

| | Blocking | | | | |
|---|---|---|---|---|---|
| | layer | | Jsc | | Effi- |
| Blocking layer | deposited | Voc | (mA/ | Fill | ciency |
| type | from | (mV) | cm²) | factor | (%) |
| No blocking layer- | 0% Tyzor ™ | 1047.31 | 9.18 | 0.446 | 4.308 |
| cell 1 | in n-butanol | | | | |
| No blocking layer- | 0% Tyzor ™ | 1082.60 | 9.34 | 0.436 | 4.419 |
| cell 2 | in n-butanol | | | | |
| Blocking layer 1- | 0.15% | 1068.62 | 9.35 | 0.471 | 4.728 |
| cell 1 | Tyzor ™ | | | | |
| | in n-butanol | | | | |
| Blocking layer 1- | 0.15% | 1071.24 | 9.06 | 0.469 | 4.572 |
| cell 2 | Tyzor ™ | | | | |
| | in n-butanol | | | | |
| Blocking layer 2- | 0.3% Tyzor ™ | 1058.70 | 10.97 | 0.465 | 5.425 |
| cell 1 | in n-butanol | | | | |
| Blocking layer 2- | 0.3% Tyzor ™ | 1060.02 | 10.92 | 0.463 | 5.379 |
| cell 2 | in n-butanol | | | | |

### Example 3—Blocking Layer

Blocking layers were applied either from 0.1 to 1% of Tyzor™ poly(n-butyl titanate) in n-butanol by spin or blade coating technique or by heating the FTO coated glass slides in 40 mM solution of aqueous TiCl₄ at 70° C. for 30 minutes (academic control). Photoelectrodes were made with and without blocking layer on FTO coated glass using screen printable colloidal TiO₂ (30 nm particle size). The thickness of the TiO₂ layer was ca. 6 microns. The TiO₂ coating was sintered at 500° C. for 30 minutes, cooled to 80° C. and immersed in a 1:1 acetonitrile/t-butanol dye solution containing 0.3 mM D35 dye (Dyenamo, Sweden) and 0.3 mM deoxycholic acid. The anodes were kept in dye solution overnight, rinsed with acetonitrile and air dried in the dark. The dye-sensitized anode was sandwiched with pyrolytically deposited platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of lithium bis(trifluorosulfon)imide and 0.5 M 4-(tertiarybutyl)pyridine in acetonitrile was injected between anode and cathode using pinhole on the cathode. The pinhole was sealed using Meltonix/glass cover using heat sealing process. A conductive silver paint was applied on the contact areas of anode and cathode and dried to form electrical contact. Three cells were fabricated for each set (denoted as cells 1, 2 and 3).

The photovoltaic performance of the fabricated cell was measured under AM 1.5 conditions at a light intensity of 97 mW/cm². The performance of fabricated photovoltaic cells was characterized using open circuit voltage (V_{oc} in mV), short circuit current density (J_{sc} in milliamperes/square centimeter), fill factor and overall photovoltaic conversion efficiency (in %) and shown in Table 3. The fill factor (FF) is defined as the ratio of the maximum power from the photovoltaic cell to the product of V_{oc} and J_{sc}.

TABLE 3
Photovoltaic characteristics of 30 nm TiO2 based
photovoltaic cells made with and without blocking
layer under 1 sun irradiation conditions

| | Blocking | | | | |
|---|---|---|---|---|---|
| | layer | | Jsc | | Effi- |
| Blocking layer | deposited | Voc | (mA/ | Fill | ciency |
| type | from | (mV) | cm²) | factor | (%) |
| Control blocking | 40 mM TiCl4 | 1075.95 | 7.84 | 0.573 | 4.853 |
| layer-cell 1 | solution | | | | |
| Control blocking | 40 mM TiCl4 | 1091.35 | 7.64 | 0.545 | 4.569 |
| layer-cell 2 | solution | | | | |
| Control blocking | 40 mM TiCl4 | 1072.01 | 6.78 | 0.613 | 4.483 |
| layer-cell 3 | solution | | | | |
| No blocking | 0% Tyzor ™ | 1039.86 | 6.33 | 0.634 | 4.194 |
| layer-cell 1 | in n-butanol | | | | |
| No blocking | 0% Tyzor ™ | 1048.39 | 5.79 | 0.639 | 3.898 |
| layer- cell 2 | in n-butanol | | | | |
| No blocking | 0% Tyzor ™ | 1052.43 | 5.86 | 0.651 | 4.035 |
| layer-cell 3 | in n-butanol | | | | |
| blocking | 0.3% Tyzor ™ | 1036.47 | 7.05 | 0.634 | 4.660 |
| layer-cell 1 | in n-butanol | | | | |
| blocking | 0.3% Tyzor ™ | 1033.73 | 7.31 | 0.637 | 4.837 |
| layer-cell 2 | in n-butanol | | | | |
| blocking | 0.3% Tyzor ™ | 1058.16 | 6.61 | 0.626 | 4.401 |
| layer-cell 3 | in n-butanol | | | | |

### Example 4—Blocking Layer

Blocking layers were applied from 0.1 to 1% of Tyzor™ poly(n-butyl titanate) in n-butanol by spin or blade coating technique (Blocking Layers—1. No blocking layer; 2. Coated from 0.3% Tyzor™; 3. Coated from 0.6% Tyzor™; 4. Coated from 1% Tyzor™). An aqueous dispersion containing 20% by weight of TiO₂ (Degussa P25 with a particle size of 21±5 nm) and 5% by weight of poly(4-vinyl pyridine) was prepared and applied on the prepared electrodes with and without blocking layer using blade coating technique. The thickness of the TiO₂ layer was ca. 6 microns. The TiO₂ coating was sintered at 500° C. for 30 minutes, cooled to 80° C. and immersed in a 1:1 acetonitrile/t-butanol dye solution containing 0.1 mM D35 dye (Dyenamo, Sweden) and 0.1 mM deoxycholic acid. The anodes were kept in dye solution overnight, rinsed with acetonitrile and air dried in the dark. The dye-sensitized anode was sandwiched with pyrolytically deposited platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (11) bis(trifluorosulfon)imide, 100 mM of lithium bis(trifluorosulfon)imide and 0.5 M 4-(tertiarybutyl)pyridine in 3-methoxypropionitrile was injected between anode and cathode using pinhole on the cathode. The pinhole was sealed using Meltonix/glass cover using heat sealing process. A conductive silver paint was applied on the contact areas of anode and cathode and dried to form electrical contact.

The photovoltaic performance of the fabricated cell was measured under indoor light irradiation conditions at 3 light levels. The performance of fabricated photovoltaic cells was characterized using open circuit voltage (V_{oc} in mV), short circuit current density (J_{sc} in microamperes/square centimeter), fill factor and overall photovoltaic conversion efficiency (in %) and shown in Table 4. The fill factor (FF) is defined as the ratio of the maximum power from the photovoltaic cell to the product of V_{oc} and J_{sc}.

TABLE 4
Photovoltaic characteristics photovoltaic cells made
using D35 with and without blocking layer under indoor
light conditions at various light intensities

| | | | | | | Percent |
|---|---|---|---|---|---|---|
| Light | Block- | | | | Power | improvement |
| Intensity | ing | Voc | Jsc | | density | in |
| (lux) | Layer | (V) | (μA/cm²) | FF | (μW/cm²) | performance |
| 375 lux | 1 | 0.81 | 21 | 0.58 | 9.87 | — |
| | 2 | 0.87 | 22 | 0.69 | 13.21 | 33.84 |
| | 3 | 0.88 | 19 | 0.66 | 11.04 | 11.85 |
| | 4 | 0.88 | 20 | 0.69 | 12.14 | 23 |
| 740 lux | 1 | 0.85 | 39 | 0.51 | 16.91 | — |
| | 2 | 0.91 | 44 | 0.61 | 24.42 | 44.41 |
| | 3 | 0.91 | 38 | 0.57 | 19.71 | 16.56 |
| | 4 | 0.91 | 40 | 0.6 | 21.84 | 29.15 |
| 1100 lux | 1 | 0.87 | 56 | 0.48 | 23.39 | — |
| | 2 | 0.93 | 66 | 0.54 | 33.15 | 41.73 |
| | 3 | 0.93 | 57 | 0.51 | 27.04 | 15.6 |
| | 4 | 0.93 | 58 | 0.54 | 29.13 | 24.54 |

### Example 5—Blocking Layer

Blocking layers were applied from 0.1 to 1% of Tyzor™ [poly(n-butyl titanate)] in n-butanol by spin or blade coating technique (Blocking Layers—1. No blocking layer; 2. Coated from 0.3% Tyzor™; 3. Coated from 0.6% Tyzor™; 4. Coated from 1% Tyzor™). Photoelectrodes were made with and without blocking layer on FTO coated glass using aqueous P25 TiO₂ with 5% polyvinylpyridine binder (21 nm particle size). The thickness of the TiO₂ layer was ca. 6 microns. The TiO₂ coating was sintered at 500° C. for 30 minutes, cooled to 80° C. and immersed in a 1:1 acetonitrile/t-butanol dye solution containing 0.3 mM BOD4 dye (WBI-synthesized, see structure at end of Examples) and 0.3 mM deoxycholic acid. The anodes were kept in dye solution overnight, rinsed with acetonitrile and air dried in the dark. The dye-sensitized anode was sandwiched with pyrolytically deposited platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in 3-methoxypropionitrile was injected between anode and cathode using pinhole on the cathode. The pinhole was sealed using Meltonix/glass cover using heat sealing process. A conductive silver paint was applied on the contact areas of anode and cathode and dried to form electrical contact.

The photovoltaic performance of the fabricated cell was measured under indoor light irradiation conditions at 3 light levels. The performance of fabricated photovoltaic cells was characterized using open circuit voltage (V_{oc} in mV), short circuit current density (J_{sc} in microamperes/square centimeter), fill factor and overall photovoltaic conversion efficiency (in %) and shown in Table 5. The fill factor (FF) is defined as the ratio of the maximum power from the photovoltaic cell to the product of V_{oc} and J_{sc}.

TABLE 5
Photovoltaic characteristics photovoltaic cells made using BOD4
with and without blocking layer under indoor light conditions

| | | | | | | Percent |
|---|---|---|---|---|---|---|
| Light | Block- | | | | Powder | improvement |
| Intensity | ing | Voc | Jsc | | density | in |
| (lux) | Layer | (V) | (μA/cm²) | FF | (μW/cm²) | performance |
| 375 lux | 1 | 0.88 | 20 | 0.54 | 9.50 | — |
| | 2 | 0.92 | 25 | 0.64 | 14.72 | 54.95 |
| | 3 | 0.9 | 20 | 0.69 | 12.42 | 30.74 |
| | 4 | 0.91 | 19 | 0.66 | 11.41 | 20.11 |
| 740 lux | 1 | 0.92 | 41 | 0.46 | 17.35 | — |
| | 2 | 0.95 | 48 | 0.52 | 23.71 | 36.66 |
| | 3 | 0.93 | 40 | 0.58 | 21.58 | 24.38 |
| | 4 | 0.95 | 37 | 0.56 | 19.68 | 13.43 |
| 1100 lux | 1 | 0.94 | 59 | 0.41 | 22.74 | — |
| | 2 | 0.97 | 70 | 0.45 | 30.56 | 34.39 |
| | 3 | 0.96 | 59 | 0.5 | 28.32 | 24.54 |
| | 4 | 0.97 | 55 | 0.5 | 26.68 | 17.33 |

### Example 6—Effect of Solvent on the Indoor Light Performance of Copper Redox Based DSPC with D35 Dye

FTO coated glasses were cut into 2 cm×2 cm size and cleaned by washing with successive 1% aqueous Triton™ X-100 solution, DI-water, and iso-propanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.1 mM D35 dye (Dyenamo, Sweden) and 0.1 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in a select solvent was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and is shown in Table 6.

TABLE 6
Photovoltaic characteristics of copper photovoltaic
cells under 720 lux indoor light exposure

| | | | | | | Power |
|---|---|---|---|---|---|---|
| | Cathode | Electrolyte | Voc | Jsc | Fill | Density in |
| Dye | catalyst | solvent | (mV) | (μA/cm²) | factor | μW/cm² |
| D35 | PEDOT | acetonitrile | 800 | 77 | 0.7 | 43.0 |
| D35 | Pyrolytic Pt | acetonitrile | 810 | 67 | 0.711 | 38.5 |
| D35 | Pyrolytic Pt | Sulfolane | 940 | 65 | 0.63 | 38.5 |
| D35 | Pyrolytic Pt | GBL | 800 | 73 | 0.694 | 40.5 |

### Example 7—Effect of Redox Couple on the Indoor Light Performance of Copper Redox Based DSPC

FTO coated glasses were cut into 2 cm×2 cm size and cleaned by washing with successive 1% aqueous Triton™ X-100 solution, DI-water, and isopropanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.1 mM D35 dye (Dyenamo, Sweden) and 0.1 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(2,9-dimethyl-1,10-phenanthroline) copper (I) bis(trifluorosulfon)imide, 50 mM bis(2,9-dimethyl-1,10-phenanthroline) copper (II) bis(trifluorosulfon)imide, 100 mM of Lithium bis(trifluorosulfon)imide and 0.5 M 4-(tertiarybutyl)pyridine in a select solvent was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and is shown in Table 7.

TABLE 7
Photovoltaic characteristics of copper photovoltaic
cells under 720 lux indoor light exposure

| | | | | | | Power |
|---|---|---|---|---|---|---|
| | Cathode | Electrolyte | Voc | Jsc | Fill | Density in |
| Dye | catalyst | solvent | (mV) | (μA/cm²) | factor | μW/cm² |
| D35 | PEDOT | acetonitrile | 800 | 77 | 0.7 | 43.0 |
| D35 | Pyrolytic Pt | acetonitrile | 810 | 67 | 0.711 | 38.5 |
| D35 | PEDOT | acetonitrile | 900 | 44 | 0.7 | 27.7 |
| D35 | Pyrolytic Pt | acetonitrile | 884 | 46 | 0.72 | 29.40 |

### Example 8—Effect of Solvent on the Indoor Light Performance of Copper Redox Based DSPC with BOD4 Dye

FTO coated glasses were cut into 2 cm×2 cm size and cleaned by washing with successive 1% aqueous Triton™ X-100 solution, DI-water, and iso-propanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.3 mM BOD4 dye and 0.3 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of lithium bis(trifluorosulfon)imide and 0.5 M 4-(tertiarybutyl)pyridine in a select solvent was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and is shown in Table 8.

TABLE 8
Photovoltaic characteristics of copper photovoltaic
cells under 720 lux indoor light exposure

| | | | | | | Power |
|---|---|---|---|---|---|---|
| | Cathode | Electrolyte | Voc | Jsc | Fill | Density in |
| Dye | catalyst | solvent | (mV) | (μA/cm²) | factor | μW/cm² |
| BOD4 | PEDOT | acetonitrile | 763 | 61 | 0.678 | 31.55 |
| BOD4 | Pyrolytic | acetonitrile | 765 | 74 | 0.648 | 36.68 |
| | Pt | | | | | |
| BOD4 | Pyrolytic | Sulfolane | 900 | 58 | 0.695 | 36.28 |
| | Pt | | | | | |
| BOD4 | PEDOT | GBL | 760 | 70 | 0.725 | 38.57 |
| BOD4 | Pyrolytic | GBL | 780 | 85 | 0.71 | 47.03 |
| | Pt | | | | | |

### Example 9—Effect of Solvent/Solvent Mixtures on the Indoor Light Performance of Copper Redox Based DSPC with 80% D13 and 20% XY1b Dye Mixture

FTO coated glasses were cut into 2 cm×2 cm size and cleaned by washing with successive 1% aqueous Triton™ X-100 solution, DI-water, and iso-propanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.24 mM D13 dye, 0.06 mM of XY1b dye (Dyenamo, Stockholm, SE) (see structure at end of Examples) and 0.3 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 250 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in a select solvent was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and photovoltaic characteristics are summarized in Tables 9A and 9B.

TABLE 9A
Photovoltaic characteristics of Indoor Photovoltaic cells with various
solvent based electrolytes at 374 lux indoor light exposure

| | | | | Power |
|---|---|---|---|---|
| | Voc | Jsc | Fill | Density |
| Electrolyte Solvent | (mV) | (μA/cm²) | factor | (μW/cm²) |
| GBL | 888 | 43 | 0.65 | 24.6 |
| Sulfolane | 981 | 40 | 0.568 | 22.29 |
| 3-methoxy propionitrile | 914 | 47 | 0.65 | 27.92 |
| Propylene carbonate | 915 | 42 | 0.67 | 25.13 |
| 1:1 Sulfolane:GBL | 911 | 43 | 0.65 | 25.46 |
| 1:1 Sulfolane:PC | 933 | 45 | 0.65 | 27.29 |
| 1:1 GBL:MPN | 916 | 44 | 0.7 | 28.21 |
| 1:1 sulfolane:PC | 940 | 38 | 0.640 | 22.86 |
| 1:1 sulfolane:MPN | 957 | 40 | 0.65 | 24.88 |

TABLE 9B
Photovoltaic characteristics of Indoor Photovoltaic cells with various
solvent based electrolytes at 1120 lux indoor light exposure

| | | | | Power |
|---|---|---|---|---|
| | Voc | Jsc | Fill | Density |
| Electrolyte Solvent | (mV) | (μA/cm²) | factors | (μW/cm²) |
| GBL | 924 | 123 | 0.579 | 65.80 |
| Sulfolane | 1016 | 107 | 0.371 | 40.33 |
| 3-methoxy propionitrile | 952 | 139 | 0.52 | 68.81 |
| Propylene carbonate | 959 | 123 | 0.488 | 57.56 |
| 1:1 Sulfolane:GBL | 949 | 123 | 0.499 | 58.24 |
| 1:1 GBL:MPN | 957 | 125 | 0.628 | 75.12 |
| 1:1 sulfolane:PC | 981 | 97 | 0.46 | 43.77 |
| 1:1 sulfolane:MPN | 1001 | 116 | 0.434 | 50.39 |

### Example 10. Effect of Solvent Ratio in GBL/Sulfolane Based Copper Redox Electrolyte on the Indoor Light Performance of DSPC with 80% D13 and 20% XY1b Dye Mixture

FTO coated glasses were cut into 2 cm×2 cm size and cleaned by washing with successive 1% aqueous Triton™ X-100 solution, DI-water, and iso-propanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.24 mM D13 dye, 0.06 mM of XY1b dye (Dyenamo, Sweden) and 0.3 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 250 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in a select solvent was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and photovoltaic characteristics are summarized in Table 10.

TABLE 10
I-V characteristics of 9/1 E3, 7z/XY1b photovoltaic cells
with various electrolytes under 2 indoor light conditions

| | 750 lux light irradiation | | | | 1120 luxirradiation | | | |
|---|---|---|---|---|---|---|---|---|
| Electrolyte | Voc | Jsc | | PD | Voc | Jsc | | PD |
| Solvent | (mV) | (μA/cm²) | ff | (μW/cm²) | (mV) | (μA/cm²) | ff | (μW/cm²) |
| GBL cell 1 | 920.97 | 80 | 0.607 | 44.72 | 932.48 | 120 | 0.560 | 62.63 |
| GBL cell 2 | 911.12 | 79 | 0.726 | 52.25 | 926.34 | 125 | 0.666 | 77.09 |
| GBL cell 3 | 925.54 | 82 | 0.638 | 48.41 | 928.26 | 126 | 0.582 | 68.79 |
| GBL -average | 919.21 | 80.33 | 0.66 | 48.46 | 929.03 | 123.67 | 0.6 | 69.5 |
| 3/1 GBL/sulfolane | 925.54 | 82 | 0.638 | 48.41 | 938.22 | 126 | 0.582 | 68.79 |
| cell 1 | | | | | | | | |
| 3/1 GBL/sulfolane | 929.80 | 96 | 0.556 | 49.64 | 943.97 | 140 | 0.509 | 67.27 |
| cell 2 | | | | | | | | |
| 3/1 GBL/sulfolane | 927.62 | 80 | 0.612 | 45.43 | 935.46 | 116 | 0.569 | 61.71 |
| cell 3 | | | | | | | | |
| 3/1 GBL/sulfolane - | 927.65 | 86 | 0.6 | 47.83 | 939.22 | 127.33 | 0.55 | 65.92 |
| average | | | | | | | | |
| 1/1 GBL/sulfolane | 942.5 | 81 | 0.588 | 44.91 | 956.75 | 123 | 0.529 | 62.26 |
| cell 1 | | | | | | | | |
| 1/1 GBL/sulfolane | 933.56 | 75 | 0.484 | 33.88 | 945.37 | 106 | 0.444 | 44.48 |
| cell 2 | | | | | | | | |
| 1/1 GBL/sulfolane | 936.99 | 72 | 0.527 | 35.55 | 948.59 | 100 | 0.480 | 45.53 |
| cell 3 | | | | | | | | |
| 1/1 GBL/sulfolane - | 937.68 | 76 | 0.53 | 38.11 | 950.24 | 109.67 | 0.48 | 50.76 |
| average | | | | | | | | |
| 1/3 GBL/sulfolane | 937.96 | 70 | 0.529 | 34.73 | 951.91 | 100 | 0.483 | 45.98 |
| cell 1 | | | | | | | | |
| 1/3 GBL/sulfolane | 946.31 | 71 | 0.545 | 36.61 | 963.11 | 104 | 0.489 | 47.6 |
| cell 2 | | | | | | | | |
| 1/3 GBL/sulfolane - | 942.14 | 70.5 | 0.54 | 35.67 | 957.51 | 102 | 0.49 | 46.79 |
| average | | | | | | | | |
| Sulfolane cell 1 | 1010.31 | 69 | 0.413 | 28.78 | 1028.37 | 89 | 0.367 | 33.58 |
| Sulfolane cell 2 | 996.65 | 67 | 0.375 | 25.02 | 1012.51 | 87 | 0.339 | 29.88 |
| Sulfolane cell 3 | 1001.62 | 76 | 0.415 | 31.57 | 1018.13 | 99 | 0.362 | 36.48 |
| Sulfolane - | 1002.86 | 70.67 | 0.40 | 28.46 | 1019.67 | 91.67 | 0.36 | 33.31 |
| average | | | | | | | | |

### Example 11. Effect of Solvent Mixtures on the Indoor Light Performance of Copper Redox Based DSPC with Various Dye and Dye Cocktails

FTO coated glasses were cut into 2 cm×2 cm size and cleaned by washing with successive 1% aqueous Triton™ X-100 solution, DI-water, and isopropanol. After drying at room temperature, the cleaned FTO glasses were treated with corona discharge (^{˜}13000 V) for approximately 20 seconds on the conducting side. A 20% aqueous P25 dispersion was blade coated (8 microns thick) on the FTO side. The coating area was trimmed to 1.0 cm². The TiO₂ coated anode was sintered at 450° C. for 30 minutes, cooled to about 80° C. and dropped into a dye solution containing 0.3 mM D35/0.3 mM chenodeoxycholic acid or 0.24 mM D35 dye, 0.06 mM of XY1b dye (Dyenamo, Sweden) and 0.3 mM chenodeoxycholic acid or 0.24 mM D13 dye, 0.06 mM of XY1b dye (Dyenamo, Sweden) and 0.3 mM chenodeoxycholic acid in 1:1 acetonitrile/t-butanol. The anodes were kept in dye solution overnight, rinsed with acetonitrile and air dried in the dark. The dye-sensitized anode was sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of 250 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine in a select solvent mixture was injected between anode and cathode using pinhole on the cathode. The pinhole was sealed using Meltonix/glass cover using heat sealing process. A conductive silver paint was applied on the contact areas of anode and cathode and dried to form electrical contact. The performance of the fabricated cell was measured under indoor light exposure conditions and photovoltaic characteristics are summarized in Tables 11A and 11B. In each instance the electrolyte solvent is a 1:1 v/v mixture.

TABLE 11A
Photovoltaic characteristics of Indoor Photovoltaic cells with varied
electrolytes and cathode catalysts at 365 lux light exposure

| | | | | | Max | Power |
|---|---|---|---|---|---|---|
| | Electrolyte | Cell Area | Voc | Jsc | Power | density |
| Dye/catalyst | solvent | (cm²) | (mV) | (μA/cm²) | (μW) | (μW/cm²) |
| D35 -cell with Pt | GBL:MPN | 1.103 | 782 | 32 | 18 | 15 |
| D35 -cell with | GBL:MPN | 1.035 | 755 | 27 | 15 | 14.49 |
| PEDOT | | | | | | |
| D35 -cell with Pt | Sulfolane:MPN | 1.050 | 880 | 35 | 18 | 17.14 |
| D35 -cell with | Sulfolane:MPN | 0.998 | 899 | 33 | 20 | 20.04 |
| PEDOT | | | | | | |
| D35:XY1b (80:20) | GBL:MPN | 0.945 | 797 | 46 | 23 | 24.33 |
| with Pt | | | | | | |
| D35:XY1b (80:20) | GBL:MPN | 1.140 | 806 | 48 | 31 | 27.19 |
| with PEDOT | | | | | | |
| D35:XY1b (80:20) | Sulfolane:MPN | 0.903 | 892 | 43 | 18 | 19.93 |
| with Pt | | | | | | |
| D35:XY1b (80:20) | Sulfolane:MPN | 0.998 | 905 | 50 | 31 | 31.06 |
| with PEDOT | | | | | | |
| D13:XY1b (80:20) | GBL:MPN | 1.050 | 893 | 46 | 26 | 24.76 |
| with Pt | | | | | | |
| D13:XY1b (80:20) | GBL:MPN | 1.103 | 889 | 42 | 31 | 28.18 |
| with PEDOT | | | | | | |
| D13:XY1b (80:20) | Sulfolane:MPN | 0.990 | 952 | 46 | 26 | 26.26 |
| with Pt | | | | | | |
| D13:XY1b (80:20) | Sulfolane:MPN | 1.045 | 970 | 48 | 34 | 32.69 |
| with PEDOT | | | | | | |

TABLE 11B
Photovoltaic characteristics of Indoor Photovoltaic cells with varied
electrolytes and cathode catalysts at 1100 lux indoor light exposure

| | Electrolyte | | | | Max | Power |
|---|---|---|---|---|---|---|
| | solvent | Cell Area | Voc | Jsc | Power | Density |
| Dye/catalyst | (v/v) | (cm²) | (mV) | (μA/cm²) | (μW) | (μW/cm²) |
| D35 -cell with Pt | GBL:MPN | 1.103 | 843 | 88 | 55 | 50.00 |
| D35 -cell with | GBL:MPN | 1.035 | 829 | 81 | 50 | 48.31 |
| PEDOT | | | | | | |
| D35 -cell with Pt | Sulfolane:MPN | 1.100 | 958 | 116 | 49 | 44.55 |
| D35 -cell with | Sulfolane:MPN | 0.998 | 967 | 97 | 62 | 53.68 |
| PEDOT | | | | | | |
| D35:XY1b (80:20) | GBL:MPN | 1.155 | 861 | 145 | 81 | 70.12 |
| with Pt | | | | | | |
| D35:XY1b (80:20) | GBL:MPN | 1.140 | 851 | 144 | 96 | 84.21 |
| with PEDOT | | | | | | |
| D35:XY1b (80:20) | Sulfolane:MPN | 1.050 | 936 | 134 | 51 | 48.57 |
| with Pt | | | | | | |
| D35:XY1b (80:20) | Sulfolane:MPN | 0.998 | 943 | 143 | 82 | 82.16 |
| with PEDOT | | | | | | |
| D13:XY1b (80:20) | GBL:MPN | 0.978 | 924 | 129 | 66 | 67.48 |
| with Pt | | | | | | |
| D13:XY1b (80:20) | GBL:MPN | 1.045 | 924 | 121 | 88 | 84.21 |
| with PEDOT | | | | | | |
| D13:XY1b (80:20) | Sulfolane:MPN | 0.990 | 998 | 136 | 54 | 54.54 |
| with Pt | | | | | | |
| D13:XY1b (80:20) | Sulfolane:MPN | 1.045 | 1006 | 139 | 85 | 81.73 |
| with PEDOT | | | | | | |

### Example 12. Effect of Mixed Redox Couple on the Indoor Light Performance of Copper Redox Based DSPC

FTO coated glasses are cut into 2 cm×2 cm size and cleaned by washing with successive 1% aqueous Triton™ X-100 solution, DI-water, and iso-propanol. After drying at room temperature, the cleaned FTO glasses are treated with Corona (^{˜}13000 V) for approximately 20 seconds on the conducting side. A 20% aqueous P25 dispersion is blade coated (8 microns thick) on the FTO side. The coating area is trimmed to 1.0 cm². The TiO₂ coated anode is sintered at 450° C. for 30 minutes, cooled to about 80° C. and dropped into a dye solution containing 0.24 mM D13 dye, 0.06 mM of XY1b dye (Dyenamo, Sweden) and 0.3 mM chenodeoxycholic acid in 1:1 acetonitrile/t-butanol. The anodes are kept in dye solution overnight, rinsed with acetonitrile and air dried in the dark. The dye-sensitized anode is sandwiched with either electrochemically deposited PEDOT catalyst or pyrolytic platinum catalyst on an FTO coated glass slide using 60 μm thick hot melt sealing film (Meltonix 1170-60PF from Solaronix, Switzerland) window by hot pressing at 125° C. for 45 seconds. A copper redox electrolyte solution consisting of
1. 250 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine;
2. 250 mM bis(6,6′-dimethyl-2,2′-bipyridine) copper (I) bis(trifluorosulfon)imide, 50 mM bis(2,9-dimethyl-1,10-phenanthroline) copper (II) bis(trifluorosulfon)imide, 100 mM of lithium bis(trifluorosulfon)imide and 0.5 M 4-(tertiarybutyl)pyridine;
3. 250 mM bis(2,9-dimethyl-1,10-phenanthroline) copper (I) bis(trifluorosulfon)imide, 50 mM bis(6,6′-dimethyl-2,2′-bipyridine) copper (II) bis(trifluorosulfon)imide, 100 mM of Lithium bis(trifluorosulfon)imide and 0.5 M 4-(tertiarybutyl)pyridine; or
4. 250 mM bis(2,9-dimethyl-1,10-phenanthroline) copper (I) bis(trifluorosulfon)imide, 50 mM bis(2,9-dimethyl-1,10-phenanthroline) copper (II) bis(trifluorosulfon)imide, 100 mM of Lithium bis(trifluorosulfon)imide and 0.5 M 4-(tertiarybutyl)pyridine;
   in 1:1 (v/v) γ-butyrolactone/3-methoxy propionitrile solvent mixture is injected between anode and cathode using pinhole on the cathode. The pinhole is sealed using Meltonix/glass cover using heat sealing process. A conductive silver paint is applied on the contact areas of anode and cathode and dried to form electrical contact. The performance of the fabricated cell is measured under indoor light exposure conditions (740 lux) and photovoltaic characteristics are summarized in Tables 12A and 12B.

TABLE 12A
Photovoltaic characteristics of Pt based photovoltaic cells with
various redox copper complex combinations at 740 lux indoor light

| | | | Voc | Jsc | Max Power | % |
|---|---|---|---|---|---|---|
| Sample ID | Cu(I) complex | Cu(II) Complex | (mV) | (μA/cm²) | (μW) | Efficiency |
| 6:1 dmbp:dmbp with Pt | Cu(dmbp)₂TFSI | Cu(dmbp)₂TFSI₂ | 937.434 | 78 | 52 | 26.032 |
| CE Cell 1 | | | | | | |
| 6:1 dmbp:dmbp with Pt | Cu(dmbp)₂TFSI | Cu(dmbp)₂TFSI₂ | 943.21 | 76 | 47 | 22.404 |
| CE Cell 2 | | | | | | |
| 6:1 dmp:dmp with Pt | Cu(dmp)₂TFSI | Cu(dmp)₂TFSI₂ | 861.81 | 56 | 36 | 16.320 |
| CE Cell 1 | | | | | | |
| 6:1 dmp:dmp with Pt | Cu(dmp)₂TFSI | Cu(dmp)₂TFSI₂ | 872.60 | 58 | 32 | 17.026 |
| CE Cell 2 | | | | | | |
| 6:1 dmbp:dmp with Pt | Cu(dmbp)₂TFSI | Cu(dmp)₂TFSI₂ | 926.75 | 74 | 38 | 20.861 |
| CE Cell 1 | | | | | | |
| 6:1 dmbp:dmp with Pt | Cu(dmbp)₂TFSI | Cu(dmp)₂TFSI₂ | 931.69 | 73 | 36 | 21.246 |
| CE Cell 2 | | | | | | |
| 6:1 dmp:dmbp with Pt | Cu(dmp)₂TFSI | Cu(dmbp)₂TFSI₂ | 894.66 | 64 | 36 | 17.946 |
| CE Cell 1 | | | | | | |
| 6:1 dmp:dmbp with Pt | Cu(dmp)₂TFSI | Cu(dmbp)₂TFSI₂ | 905.89 | 64 | 38 | 18.295 |
| CE Cell 2 | | | | | | |

TABLE 12B
Photovoltaic characteristics of electrochemical PEDOT based photovoltaic cells
with various redox copper complex combinations at 740 lux indoor light

| | | | Voc | Jsc | Max Power | % |
|---|---|---|---|---|---|---|
| Sample ID | Cu(I) complex | Cu(II) Complex | (mV) | (μA/cm²) | (μW) | Efficiency |
| 6:1 dmbp:dmbp with | Cu(dmbp)₂TFSI | Cu(dmbp)₂TFSI₂ | 941.070 | 80 | 51 | 25.739 |
| PEDOT CE Cell 1 | | | | | | |
| 6:1 dmbp:dmbp with | Cu(dmbp)₂TFSI | Cu(dmbp)₂TFSI₂ | 934.981 | 77 | 49 | 24.659 |
| PEDOT CE Cell 2 | | | | | | |
| 6:1 dmp:dmp with | Cu(dmp)₂TFSI | Cu(dmp)₂TFSI₂ | 851.83 | 58 | 37 | 17.533 |
| PEDOT CE-Cell 1 | | | | | | |
| 6:1 dmp:dbp with | Cu(dmp)₂TFSI | Cu(dmp)₂TFSI₂ | 853.05 | 62 | 36 | 18.060 |
| PEDOT CE-Cell 2 | | | | | | |
| 6:1 dmbp:dmp with | Cu(dmbp)₂TFSI | Cu(dmp)₂TFSI₂ | 929.05 | 75 | 50 | 23.742 |
| PEDOT CE-Cell 1 | | | | | | |
| 6:1 dmbp:dbp with | Cu(dmbp)₂TFSI | Cu(dmp)₂TFSI₂ | 927.52 | 75 | 42 | 23.356 |
| PEDOT CE-Cell 2 | | | | | | |
| 6:1 dmp:dmbp with | Cu(dmp)₂TFSI | Cu(dmbp)₂TFSI₂ | 882.30 | 65 | 38 | 19.760 |
| PEDOT CE-Cell 1 | | | | | | |
| 6:1 dmp:dmbp with | Cu(dmp)₂TFSI | Cu(dmbp)₂TFSI₂ | 879.40 | 66 | 36 | 20.051 |
| PEDOT CE- Cell 2 | | | | | | |

### Example 13

Fluorine-doped tin oxide (FTO) coated glasses were cut into 2 cm×2 cm size and cleaned by washing with successive 1% aqueous Triton™ X-100 solution, deionized (DI) water, and isopropanol. After drying at room temperature, the cleaned FTO glasses were treated with corona discharge (^{˜}13000 V) for approximately 20 seconds on the conducting side. An aqueous dispersion containing 20% by weight of TiO₂ (Degussa P25 with a particle size of 21±5 nm) and 5% by weight of poly(4-vinyl pyridine) was prepared and blade coated (6-8 microns thick) on the FTO coated side of the glass. The coating area was trimmed to 1.0 cm². The TiO₂ coated anode was sintered at 450° C. for 30 minutes, cooled to about 80° C. and dropped into a dye cocktail solution containing 0.3 mM D35 dye and 0.3 mM chenodeoxycholic acid in 1:1 acetonitrile/t-butanol. The anodes were kept in dye solution overnight, rinsed with acetonitrile and air dried in the dark.

### Cathode Preparation

Solution 1 was prepared by dissolving 0.04 g EDOT (3,4-dioxyethylenethiophene) in 2 mL of n-butanol. Solution 2 was prepared by dissolving 1 g of 40% ferric tosylate solution in n-butanol (0.4 g of Fe salt in 0.6 g of BuOH), 0.033 g 37% HCl, in 0.5 ml of BuOH. Solution 2 solutions were mixed with various amounts of graphenes such as 0%, 5%, and 10% (weight to EDOT monomer).

Solutions 1 and 2 (with various amounts of graphenes) were mixed well and spin coated on clean fluorine-tin oxide coated glass substrate (substrate was cleaned by 1% Triton™ X100/water/IPA/corona treatment, and heated by hair dryer for 5 seconds before coating) A spin speed of 1000 rpm for 1 minute was used. The resulting films were air dried, the coating was rinsed with MeOH, dried and heat treated at 100° C. for 30 minutes.

### Cell Fabrication

Prepared cathodes were sandwiched with dye-sensitized anodes using 60 μm thick hot melt sealing film (Meltonix 1170-60PF from Solaronix, Switzerland) window by hot pressing at 125° C. for 45 seconds. A copper redox electrolyte solution consisting of 200 mM bis(6,6′-dimethyl-2,2′-bipyridine) copper (I) bis(trifluorosulfon)imide, 50 mM bis(6,6′-dimethyl-2,2′-bipyridine) copper (II) bis(trifluorosulfon)imide, 100 mM of lithium bis(trifluorosulfon)imide and 0.5 M 4-(tertiarybutyl)pyridine in acetonitrile was injected between anode and cathode using pinhole on the cathode. The pinhole was sealed using Meltonix/glass cover using heat sealing process. A conductive silver paint was applied on the contact areas of anode and cathode and dried to form electrical contact. Two cells were fabricated for each cathode catalytic material. An electrochemically polymerized PEDOT containing cathode and a pyrolytically deposited platinum containing cathode were used as external controls.

The performance of the fabricated cell was measured under AM 1.5 conditions at a light intensity of 97 mW/cm². The performance of fabricated photovoltaic cells was characterized using open circuit voltage (V_{oc} in mV), short circuit current density (J_{sc} in milliamperes/square centimeter), fill factor and overall photovoltaic conversion efficiency (in %) and shown in Table 13. The fill factor (FF) is defined as the ratio of the maximum power from the photovoltaic cell to the product of V_{oc} and J_{sc}.

TABLE 13
Photovoltaic characteristics of copper redox based dye-sensitized
photovoltaic cells with various graphene content based chemically
polymerized PEDOT cathodes under 1 sun irradiation conditions

| | | | | Photovoltaic |
|---|---|---|---|---|
| Catalyst on the | J_{sc} | V_{oc} | Fill | Conversion |
| Cathode | (mA/cm²) | (mV) | factor | efficiency (%) |
| Chemical PEDOT with | 5.84 | 1081 | 0.45 | 2.85 |
| 0% graphene | 6.59 | 1086 | 0.46 | 3.27 |
| Chemical PEDOT with | 7.07 | 1080 | 0.43 | 3.25 |
| 5% graphene | 7.39 | 1053 | 0.45 | 3.49 |
| Chemical PEDOT with | 6.53 | 1084 | 0.42 | 2.94 |
| 10% graphene | 7.13 | 1073 | 0.43 | 3.28 |
| Electrochemical PEDOT | 6.50 | 1092 | 0.44 | 3.12 |
| with 0% graphene | 6.85 | 1077 | 0.45 | 3.29 |
| Pyrolytic platinum | 5.98 | 1050 | 0.27 | 1.72 |
| | 6.08 | 1055 | 0.32 | 2.05 |

### Example 14. Electropolymerized PEDOT with Graphenes

Fluorine-doped tin oxide (FTO) coated glasses were cut into 2 cm×2 cm size and cleaned by washing with successive 1% aqueous Triton™ X-100 solution, deionized (DI) water, and isopropanol. After drying at room temperature, the cleaned FTO glasses were treated with corona discharge (^{˜}13000 V) for approximately 20 seconds on the conducting side. An aqueous dispersion containing 20% by weight of TiO₂ (Degussa P25 with a particle size of 21±5 nm) and 5% by weight of poly(4-vinyl pyridine) was prepared and blade coated (6-8 microns thick) on the FTO coated side of the glass. The coating area was trimmed to 1.0 cm². The TiO₂ coated anode was sintered at 450° C. for 30 minutes, cooled to about 80° C. and dropped into a dye cocktail solution containing 0.3 mM D35 dye and 0.3 mM chenodeoxycholic acid in 1:1 acetonitrile/t-butanol. The anodes were kept in dye solution overnight, rinsed with acetonitrile and air dried in the dark.

### Cathode Preparation:

872 mg Tetra-n-butylammonium hexafluorophosphate (TBHFP) was dissolved in 2.25 mL of acetonitrile (ACN) followed by adding 240 μL of 3,4-ethylenedioxythiophene (EDOT). The resulting solution was added to 225 mL of aqueous sodium dodecylsulfate solution and the resulting suspension was ultrasonicated for 1 hour to get clear emulsion.

The resulting emulsion was used for electrodeposition of PEDOT under galvanostatic (constant current) mode. The current was set to 200 μA, time was set to 150 s. The working electrode was 2 cm×2 cm FTO-coated glass slide; the counter electrode was 2 cm×2.5 cm FTO-coated glass slide. Both electrodes were partially submerged in the EDOT solution with FTO coated sides facing each other, the distance between the electrodes being 2 cm. The PEDOT coated slides were rinsed with isopropanol, allowed to dry under ambient conditions, and stored under ACN.

The EDOT emulsion was also prepared with various amounts of graphenes (to that of EDOT concentration) and used for electrodeposition of PEDOT/graphene composite catalysts. PEDOT was also electrodeposited on predeposited graphene containing electrodes.

### Cell Fabrication

Prepared cathodes were sandwiched with dye-sensitized anodes using 60 μm thick hot melt sealing film (Meltonix 1170-60PF from Solaronix, Switzerland) window by hot pressing at 125° C. for 45 seconds. A copper redox electrolyte solution consisting of 250 mM bis(6,6′-dimethyl-2,2′-bipyridine) copper (I) bis(trifluorosulfon)imide, 50 mM bis(6,6′-dimethyl-2,2′-bipyridine) copper (11) bis(trifluorosulfon)imide, 100 mM of lithium bis(trifluorosulfon)imide and 0.5 M 4-(tertiarybutyl)pyridine in sulfolane was injected between anode and cathode using pinhole on the cathode. The pinhole was sealed using Meltonix/glass cover using heat sealing process. Conductive silver paint was applied on the contact areas of anode and cathode and dried to form electrical contact. Two cells were fabricated for each cathode catalytic material. An electrochemically polymerized PEDOT containing cathode and a pyrolytically deposited platinum containing cathode were used as external controls.

The performance of the fabricated cell was measured under indoor light irradiation conditions at 740 lux. The performance of fabricated photovoltaic cells was characterized using open circuit voltage (V_{oc} in mV), short circuit current density (J_{sc} in milliamperes/square centimeter), fill factor and overall photovoltaic conversion efficiency (in %) and shown in Tables 14A and 14B. The fill factor (FF) is defined as the ratio of the maximum power from the photovoltaic cell to the product of V_{oc} and J_{sc}.

TABLE 14A
Photovoltaic characteristics of copper redox based dye-sensitized
photovoltaic cells with various graphene content based electro-
polymerized PEDOT cathodes using mixed EDOT/graphene emulsions

| Graphene/EDOT ratio | | | | | Power |
|---|---|---|---|---|---|
| in galvanostatic | Deposition | Voc | Jsc | | density |
| bath | Time (s) | (mV) | (μA/cm²) | FF | (μW/cm²) |
| No graphene (control) | 120 | 741 | 31 | 0.721 | 17 |
| 0.5/10 premixed using | 120 | 770 | 33 | 0.712 | 18 |
| ultrasonic bath | | | | | |
| 0.5/10 premixed using | 120 | 764 | 36 | 0.706 | 19 |
| ultrasonic probe | | | | | |
| 01/10 premixed using | 120 | 780 | 38 | 0.716 | 21 |
| ultrasonic bath | | | | | |
| 02/10 premixed using | 120 | 766 | 38 | 0.713 | 21 |
| ultrasonic bath | | | | | |
| 02/10 premixed using | 120 | 786 | 36 | 0.705 | 20 |
| ultrasonic probe | | | | | |

TABLE 14B
Photovoltaic characteristics of copper redox based
dye-sensitized photovoltaic cells with PEDOT electro-
polymerized on graphene coated cathodes

| | Electro- | | Jsc | | Power |
|---|---|---|---|---|---|
| Graphene deposition | Deposition | Voc | (μA/ | | density |
| process | Time (s) | (mV) | cm²) | FF | (μW/cm²) |
| No graphene (control) | 60 | 841 | 46 | 0.705 | 27 |
| | 120 | 846 | 45 | 0.705 | 27 |
| graphene coated from | 60 | 857 | 47 | 0.687 | 28 |
| n-BuOH | 120 | 862 | 48 | 0.713 | 29 |
| graphene coated from | 60 | 837 | 42 | 0.680 | 24 |
| 1 mM SDS in n-BuOH | 120 | 863 | 44 | 0.701 | 27 |
| graphene coated from | 60 | 838 | 44 | 0.699 | 26 |
| 10 mM SDS in n-BuOH | 120 | 843 | 42 | 0.706 | 25 |

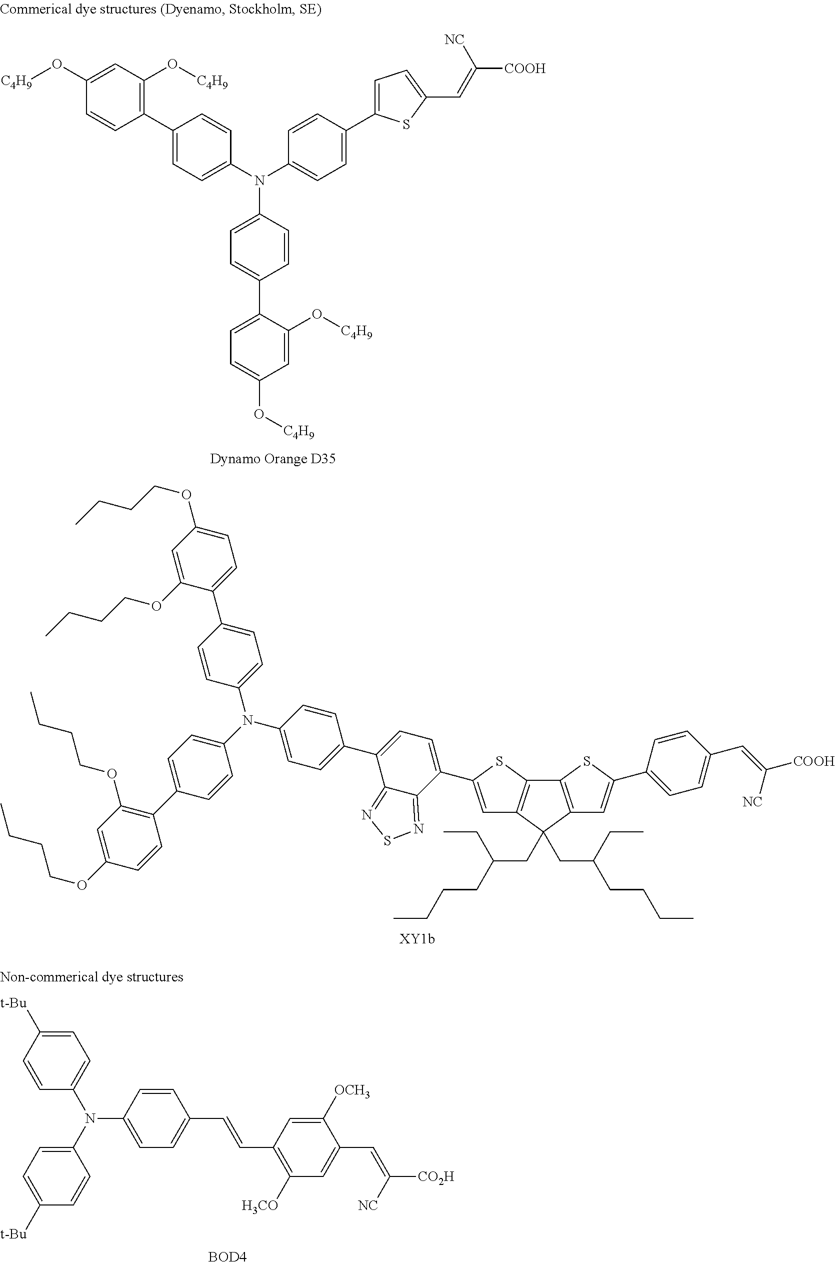

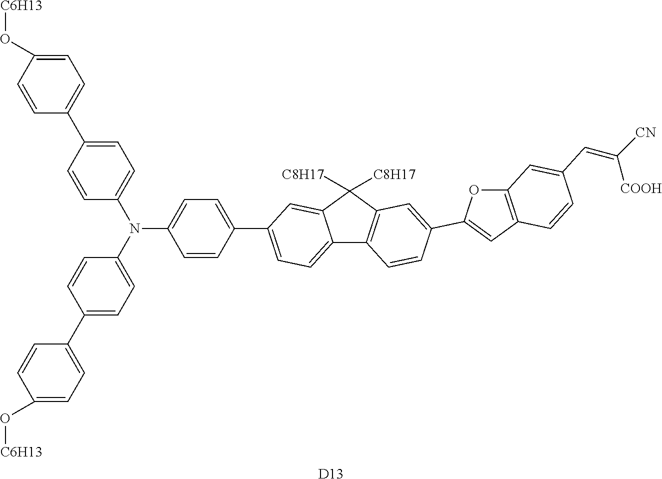

1. A dye-sensitized photovoltaic cell comprising:
a cathode;
an electrolyte;
a porous dye-sensitized titanium dioxide film layer;
an anode; and
a nonporous hole-blocking layer interposed between the anode and the dye-sensitized titanium dioxide film layer.

2. The dye-sensitized photovoltaic cell of claim 1, wherein the nonporous hole-blocking layer comprises an organotitanium compound.

3. The dye-sensitized photovoltaic cell of claim 2, wherein the organotitanium compound is a titanium alkoxide.

4. The dye-sensitized photovoltaic cell of claim 3, wherein the titanium alkoxide is a polymeric titanium alkoxide.

5. The dye-sensitized photovoltaic cell of claim 4, wherein the polymeric titanium alkoxide is poly(n-butyl titanate).

6. The dye-sensitized photovoltaic cell of claim 1, wherein the nonporous hole blocking layer comprises anatase.

7. The dye-sensitized photovoltaic cell of claim 1, wherein the thickness of the nonporous hole blocking layer is 20-100 nm.

8. The dye-sensitized photovoltaic cell of claim 1, wherein the anode comprises a transparent conducting oxide (TCO)-coated glass, a TCO coated transparent plastic substrate, or a thin metal foil.

9. The dye-sensitized photovoltaic cell of claim 8, wherein the transparent conducting oxide is fluorine-doped tin oxide, indium-doped tin oxide, or aluminum-doped tin oxide.

10. The dye-sensitized photovoltaic cell of claim 8, wherein the transparent plastic substrate comprises PET or PEN.

11. A method of preparing a dye-sensitized photovoltaic cell according to claim 1 comprising the step of applying the nonporous blocking layer on the anode.

12. The method of claim 11 wherein the nonporous blocking layer comprises a polymeric titanium alkoxide.

13. The method of claim 12, wherein the polymeric titanium alkoxide is poly(n-butyl titanate).

14. The method of claim 11, wherein the nonporous blocking layer is applied to the anode using gravure, silkscreen, slot, spin, spray or blade coating.

15. The method of claim 11, further comprising the step of forming a composite catalytic layer on the cathode.

16. The method of claim 15, wherein the catalytic layer comprises a mixture of graphenes with one or more polymers selected from the group consisting of polythiophenes, polypyrroles, and polyanilines.

17. The method of claim 16, wherein the polythiophene is PEDOT.

18. The method of claim 17, wherein the ratio of graphene to PEDOT is from 0.5:10 to 2:10.

19. The method of claim 18, wherein the PEDOT is formed prior to deposition on the cathode.

20. The method of claim 18, wherein the graphene/PEDOT is formed by the steps of depositing graphene on an electrode to form a graphene layer; and
electrodepositing the polymer on the graphene layer.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)
